(19) United States
(12) Patent Application Publication
(10) Pub. No.: US 2023/0260853 A1
(43) Pub. Date: Aug. 17, 2023

(54) METHOD FOR DETERMINING FINE PARTICLE DEFECTS ON SILICON WAFER

(71) Applicant: SK Siltron Co., LTD., Gyeongsangbuk-do (KR)

(72) Inventor: Woo Young PARK, Seoul (KR)

(21) Appl. No.: 17/732,884

(22) Filed: Apr. 29, 2022

(30) Foreign Application Priority Data
Feb. 15, 2022 (KR) 10-2022-0019402

(51) Int. Cl. H01L 21/66; G06T 7/00; G01N 21/88

(52) U.S. Cl. CPC H01L 22/12; H01L 22/26; G06T 7/0008; G01N 21/8851; G06T 2207/30148; G01N 2021/888

(57) ABSTRACT

Disclosed is a method for determining fine particle defects on a silicon wafer that includes detecting first defects on the surface of the silicon wafer, depositing a thin film thereon, detecting second defects thereon, determining whether or not additional defects are formed after deposition of the thin film, and removing noise therefrom. Using the method, it is possible to identify ultrafine particle defects present on the surface of the silicon wafer before detection of the first defects.

This application claims the benefit of Korean Patent Application No. 10-2022-0019402, filed on Feb. 15, 2022, which is hereby incorporated by reference as if fully set forth herein.

### BACKGROUND OF THE INVENTION

### Field of the Invention

The present invention relates to a method of determining fine particle defects on a silicon wafer, and more particularly to a method of determining fine particle defects on a silicon wafer that includes forming a silicon nitride film on the surface of the silicon wafer and removing noise defects.

### Discussion of the Related Art

A silicon wafer used as a material for producing electronic components such as semiconductors or solar cells is manufactured by growing a single-crystal silicon ingot using a Czochralski (CZ) method or the like and then performing a series of processes thereon. Subsequently, a semiconductor is manufactured through a series of processes such as injecting predetermined ions into the wafer and then forming a circuit pattern thereon.

Silicon wafers are the most basic material for semiconductor devices, and impurities or defects present thereon have a fatal impact on semiconductor manufacturing processes or finished semiconductor products.

In particular, defects, such as bumps or pits, caused by the wafer itself, and bump defects such as particles or PID (polishing-induced defects) on the wafer surface due to the influence of the wafer-manufacturing environment may cause fatal defects in any device manufacturing process and thus greatly deteriorate yield.

As wafer surface inspection devices, there are various surface inspection devices, including particle counter equipment such as an SP3 and SP5 from KLA-Tencor, and these devices are capable of detecting defects having a size up to 13 nm (nanometers). Information about defects detected using a wafer surface inspection device can be obtained through a scanning electron microscope (SEM) and the obtained information can contribute to improvements in the wafer manufacturing-process and wafer quality. This enables excellent silicon wafers to be supplied to customers.

However, there remains a problem in which localized light scattering (LLS) increases after a process of depositing a nitride film on a wafer in the process of manufacturing the device.

In order to detect particle defects having a size that cannot be detected using an inspection device (hereinafter referred to as “ultrafine particle defects”), evaluation using silicon nitride film deposition is performed.

In the conventional ultrafine particle defect evaluation process, 13 nm (nanometer) LLS inspection is performed on a silicon wafer, a silicon nitride film (Si3N4) is deposited thereon, 26 nm LLS inspection is performed thereon and then additional defects are observed.

FIG. 1 is a diagram showing the results of conventional ultrafine particle defect evaluation.

As shown in FIG. 1, particle defects P are detected through 13 nm LLS inspection. Also, the particle defects P are changed to bump defects B due to the deposition of the silicon nitride film, and the bump defects B are detected on the surface of the silicon wafer. Ultrafine particle defects W_B, which were present on the surface of the silicon wafer but were not detected through 13 nm LLS inspection due to the small size thereof, are changed due to deposition of the silicon nitride film, and can thus be detected through 26 nm LLS inspection. When the additional defects on the right side of FIG. 1 are observed, only the ultrafine particle defects W_B, excluding the bump defects B present at the same position as the existing particle defects P, can be detected.

However, the conventional ultrafine particle defect evaluation process described above has the following problems.

After 13 nm LLS inspection and deposition of silicon nitride film, silicon wafers are contaminated due to exposure to the atmosphere, deposition equipment, and the like. Therefore, in order to evaluate ultrafine particle defects, it is necessary to remove noise caused by such contamination.

### SUMMARY OF THE INVENTION

Accordingly, the present invention is directed to a method of determining fine particle defects on a silicon wafer that substantially obviates one or more problems due to limitations and disadvantages of the related art.

An object of the present invention is to provide a method of accurately determining fine particle defects on a silicon wafer.

However, the objects to be accomplished by the present invention are not limited to the above-mentioned object, and other objects not mentioned herein will be clearly understood by those skilled in the art from the following description.

In order to accomplish the above and other objects, provided is a method for determining ultrafine particle defects, including detecting first defects on a surface of a silicon wafer, forming a thin film on the silicon wafer, detecting second defects on the surface of the silicon wafer having the thin film formed thereon, comparing the first defects with the second defects to determine whether or not there are additional defects, and removing noise from the additional defects.

The step of determining whether or not there are additional defects may include determining second defects located beyond a predetermined distance from the first defects to be additional defects.

The step of removing noise from the additional defects may include assigning a specific symbol to each of second defects based on characteristics of second defects by a second defect detector.

The specific symbol assigned to each of the second defects may be A, B, or C, and among the specific symbols A to C, the second defects having the specific symbol C may be the largest and the seconds defect having the specific symbol B may be the smallest.

The second defects having the specific symbol C may be determined to be noise.

The second defects having the specific symbol A may include particle defects and bump defects.

The particle defects, among the second defects having the specific symbol A, may be determined to be noise.

The bump defects, among the second defects having the specific symbol A, may be determined to be noise.

The second defects having the specific symbol B may include ultrafine particle defects and bump defects.

The ultrafine particle defects, among the second defects having the specific symbol B, may have a smaller size than particle defects, among the second defects having the specific symbol A.

The bump defects, among the second defects having the specific symbol B, may have a smaller size than bump defects, among the second defects having the specific symbol A.

The first defects having a 1-1 size before the formation of the thin film may be changed to second defects having a 2-1 size, which is larger than the 1-1 size, after the formation of the thin film.

Among the second defects having the specific symbol B, second defects smaller than the 2-1 size may be determined to be bump defects.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a diagram showing the results of conventional ultrafine particle defect evaluation;

FIG. 2 is a view showing an embodiment of a method for evaluating ultrafine particle defects according to the present invention;

FIGS. 3A to 3D illustrate defects on the surface of a silicon wafer in each step of the method of evaluating ultrafine particle defects according to the present invention;

FIGS. 4A to 4C show SEM images of defects, each having a specific symbol A, B, or C assigned thereto;

FIG. 5 is a graph showing a change in rough bin number before and after deposition of a silicon nitride film;

FIG. 6 is a graph showing the size of the defects of FIG. 5 after thin film deposition;

FIGS. 7A to 7G show size changes of defects before and after thin film deposition;

FIG. 8 shows the ratio of the defects determined to be noise to the total number of sample defects in FIGS. 7A to 7G; and

FIG. 9 shows the average size of defects after thin film deposition in each size region of defects.

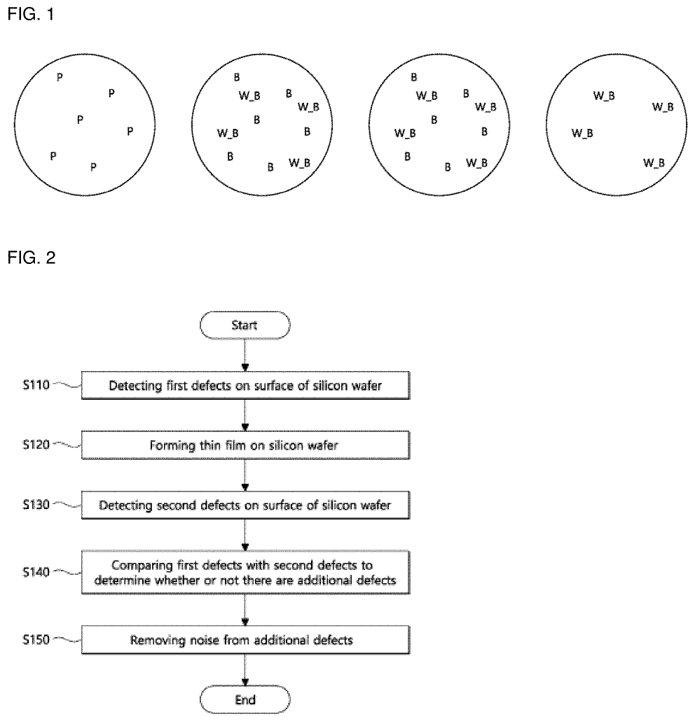

### DETAILED DESCRIPTION OF THE INVENTION

Hereinafter, reference will now be made in detail to the preferred embodiments of the present invention, examples of which are illustrated in the accompanying drawings for better understanding of the present invention.

However, the embodiments according to the present invention may be implemented in various other forms, and should not be construed as limiting the scope of the present invention, and are provided to more completely explain the present invention to those of ordinary skill in the art.

In addition, relational terms such as “first”, “second”, “upper”, and “lower”, as used below, do not necessarily require or imply any physical or logical relationship or order between such entities or elements, and may be used only to distinguish one entity or element from another entity or element.

FIG. 2 is a view showing an embodiment of a method for evaluating ultrafine particle defects according to the present invention.

The embodiment of the method for evaluating ultrafine particle defects according to the present invention includes detecting first defects on the surface of a silicon wafer (S110), forming a thin film on the silicon wafer (S120), detecting second defects on the surface of the silicon wafer (S130), comparing the first defects with the second defects to determine whether or not there are additional defects (S140), and removing noise from the additional defects (S150).

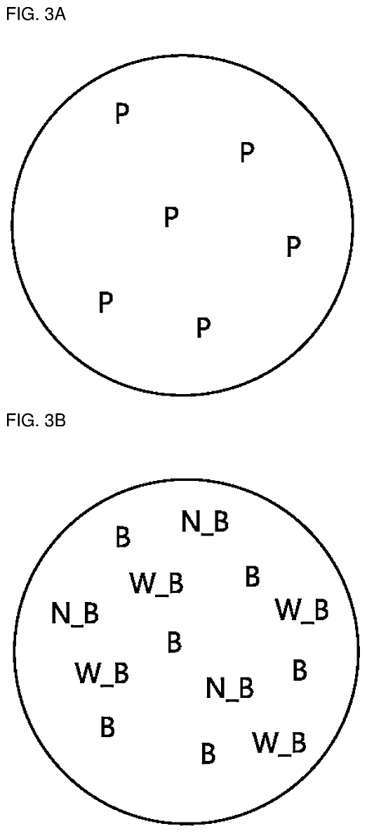

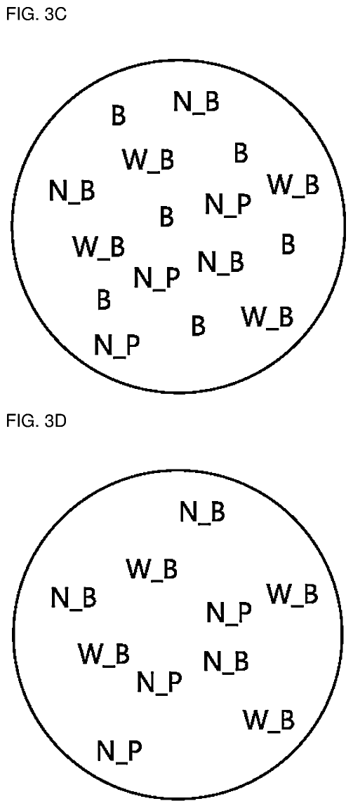

In the detecting the first defects on the surface of the silicon wafer, LLS inspection at a first wavelength may be performed; for example, LLS inspection at 13 nm may be performed. As shown in FIG. 3A, particle defects P may be detected on the surface of the silicon wafer.

In addition, a thin film may be formed on the surface of the silicon wafer. For example, a silicon nitride (Si3N4) film may be formed through low-pressure chemical vapor deposition (LPCVD), and at this time, the aforementioned defects other than the particle defects P may be changed through the thin film.

That is, first defects P have a 1-1 size before deposition of the thin film, and are converted to second defects (B in FIG. 3B) having a 2-1 size, larger than the size of the first defects, after deposition of the thin film.

In FIG. 3B, in addition to the particle defects (B), ultrafine particle defects W_B, which were present on the surface of the silicon wafer but were not detected upon LLS inspection using a first wavelength due to the small size thereof, are converted from the first defects and observed. In addition, after the first defect detection process, noise bump defects N_B are formed due to the first defect detection equipment or the like, and are observed on the surface of the silicon wafer.

Here, FIG. 3B shows defects present on the surface of the silicon wafer in addition to the particle defects (B) before and after thin film deposition, rather than the actual LLS inspection.

In addition, as shown in FIG. 3C, after a thin film such as a silicon nitride film is deposited, noise particle defects N_P may be formed on the surface of the thin film by deposition equipment or the like, and the particle defects P may appear as bump defects B.

In addition, additional defects that are determined to be present when comparing the first defects with the second defects are shown in FIG. 3D. That is, the positions of the first defects observed during detection of the first defects are compared with the positions of the second defects observed during detection of the second defects. As a result, when the positions of the first defects are determined not to be the same as those of the second defects, that is, when the second defects are located beyond a predetermined distance, for example, 300 nanometers, from the first defects, additional defects are determined to be present.

In addition, when the first defects and the second defects are located within the predetermined distance from each other, they are determined to be the same defects, and defects that were observed as first defects but were not observed as second defects are determined to be removal defects. At this time, among the above-described same defects, additional defects, and removal defects, the additional defects are identified in the method of determining the fine particle defects of the silicon wafer according to the present embodiment.

Hereinafter, the step (S150) of removing noise from the additional defects will be described in detail. More particularly, when the bump defects B converted from the particle defects of FIG. 3A are removed in the step of identifying the additional defects, among the four types of defects of FIG. 3C, three types of defects, namely, ultrafine particle defects W_B, noise bump defects N_B, and noise particle defects N_P, can be detected, as shown in FIG. 3D, and the noise bump defects N_B and the noise particle defects N_P can be removed from the three types of defects in step (S150).

In step (S150) of removing noise from the additional defects, a specific symbol may be assigned to each second defect by the device for detecting the second defects depending on the characteristics of the second defects.

Specifically, a specific symbol A, B, or C may be assigned to each of the second defects. Among the second defects having specific symbols A to C, the second defect having a size of C may be the largest and the second defect having a size of B may be the smallest.

For example, the specific symbol may be a rough bin number. In this case, A may be [0], B may be [100], and C may be [200]. In addition, the shape of each second defect may be observed using a scanning electron microscope (SEM) or the like.

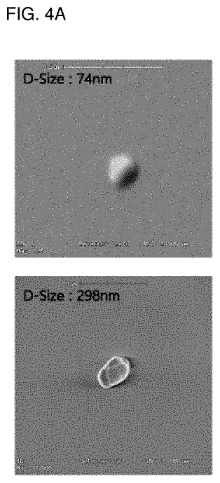

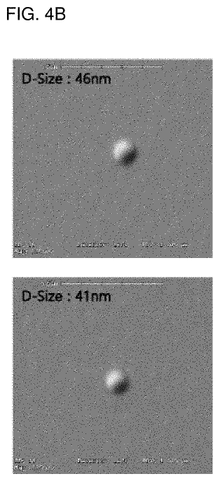

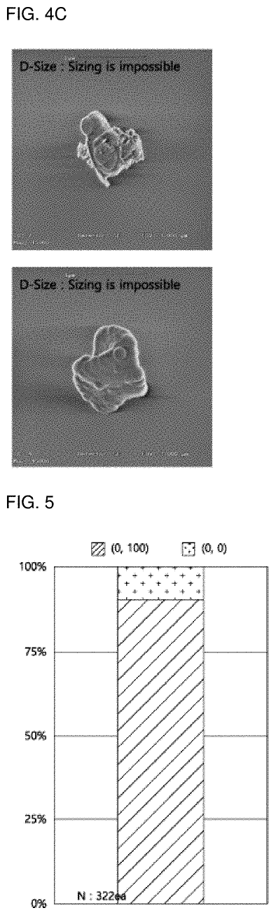

FIGS. 4A to 4C show SEM images of defects to which a specific symbol A, B or C is assigned.

As can be seen from FIGS. 4A to 4C, defects having specific symbols A, B, and C, that is, defects represented by rough bin numbers [0], [100], and [200], have the same size as in the SEM image. It can be seen through SEM analysis that [0] represents particle defects or bump defects, [100] represents bump defects, and [200] represents defects having an area where sizing is impossible. Here, the defects of the rough bin number [200] have a size of 200 micrometers or more, but the size of the ultrafine particle defects to be detected in the present invention cannot be more than 200 micrometers. Therefore, a defect having a rough bin number of [200], that is, a specific symbol of C, can be determined to be noise.

FIG. 5 is a graph showing a change in rough bin number before and after deposition of a silicon nitride film. A total of 322 defects were observed by SEM, and the rough bin numbers thereof were also confirmed. The first value in (parentheses) is the value before silicon nitride film deposition, and the second value is the value after silicon nitride film deposition. Most defects have a value of [0] before silicon nitride film deposition and a value of [100] after silicon nitride film deposition.

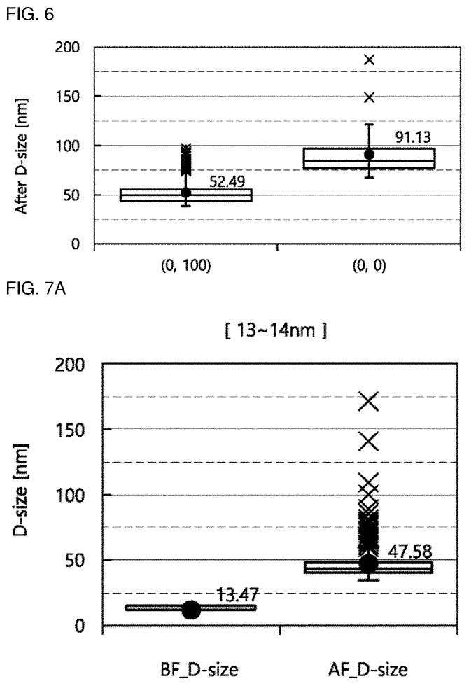

FIG. 6 is a graph showing the size of the defects of FIG. 5 after thin film deposition.

It can be seen that defects having different rough bin numbers before and after thin film deposition have an average size of 52.49 nanometers after thin film deposition, and defects having the same rough bin number before and after thin film deposition have an average size of 91.13 nanometers after thin film deposition.

In addition, second defects having a specific symbol A, that is, a rough bin number of [0], include both particle defects and bump defects, and second defects having a specific symbol B, that is, a rough bin number of [100], include ultrafine particle defects and bump defects.

In addition, it can be seen that the bump defects represented by the rough bin number of [0] have a larger size than the bump defects represented by the rough bin number of [100]. Therefore, the bump defects represented by the rough bin number of [0] in FIG. 3C may be assumed to be noise bump defects N_B and determined to be noise.

In addition, the second defects represented by the rough bin number of [0] may also include particle defects. Here, the particle defects may be assumed to be the noise particle defects N_P of FIG. 3C and determined to be noise.

In addition, it can be estimated that, among the second defects having the specific symbol B represented by the rough bin number of [100], the ultrafine particle defects (W_B in FIGS. 3B to 3D) have a smaller size than those of particle defects (N_P in FIGS. 3C to 3D), among the fine particle defects having the specific symbol A represented by rough bin number of [0].

Therefore, based on the above method, smaller second defects having a specific symbol B represented by rough bin number of [100] are determined to be ultrafine particle defects (also W_B in FIGS. 3B to 3D), and remaining defects are determined to be noise.

In addition, among the second defects, having a specific symbol B, the second defects having a size smaller than a size 2-1 may be determined to be bump defects. That is, the first defects having a size 1-1 before thin film formation are detected as second defects having a size 2-1, which is larger than the size 1-1, after thin film formation, so second defects having a size smaller than the size 2-1 may be determined to be noise bump defects N_B and determined to be noise.

In addition, a criterion is required in order to determine whether or not there are bump defects as to be noise or ultrafine particle defects. Ultrafine particle defects are not detected before deposition of a thin film such as a silicon nitride film and are thus predicted to be smaller than common defects. Therefore, the criterion can be established using the size of the common defects.

It was found that the size of the smallest detectable defect before deposition of the thin film was 13 nanometers, but the defect increased in size from 13 nanometers to about 43.58 nanometers after deposition of the thin film. Accordingly, defects having a size of 43.58 nanometers or more were determined to be noise bump defects and removed, and defects having a size smaller than these defects were determined to be ultrafine particle defects.

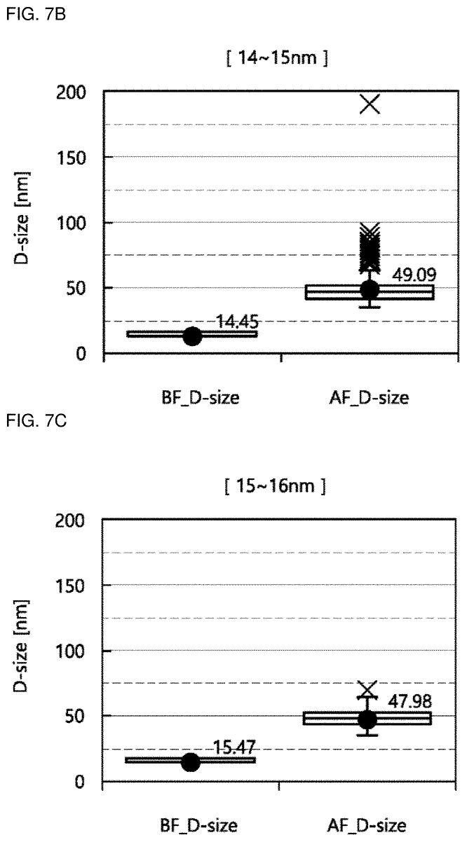

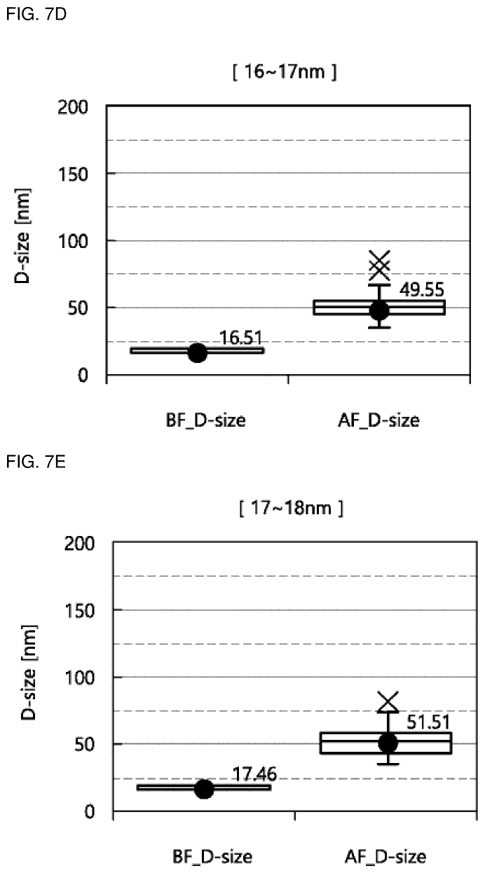

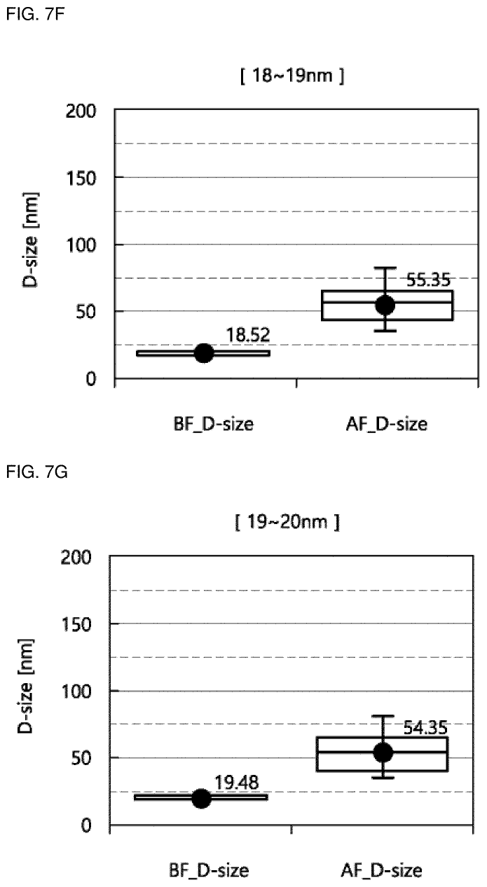

FIGS. 7A to 7G show size changes of defects before and after thin film deposition.

For example, in FIG. 7A, defects having an average size of 13.47 nanometers and a size range of 13 to 14 nanometers before thin film deposition have an increased average size of 47.58 nanometers after thin film deposition. In addition, it can be seen from FIGS. 7B to 7G that the average size of defects after thin film deposition is increased compared to before thin film deposition. In FIGS. 7A to 7G, the data represented by “x” are abnormally large compared to other data and are thus determined to be noise.

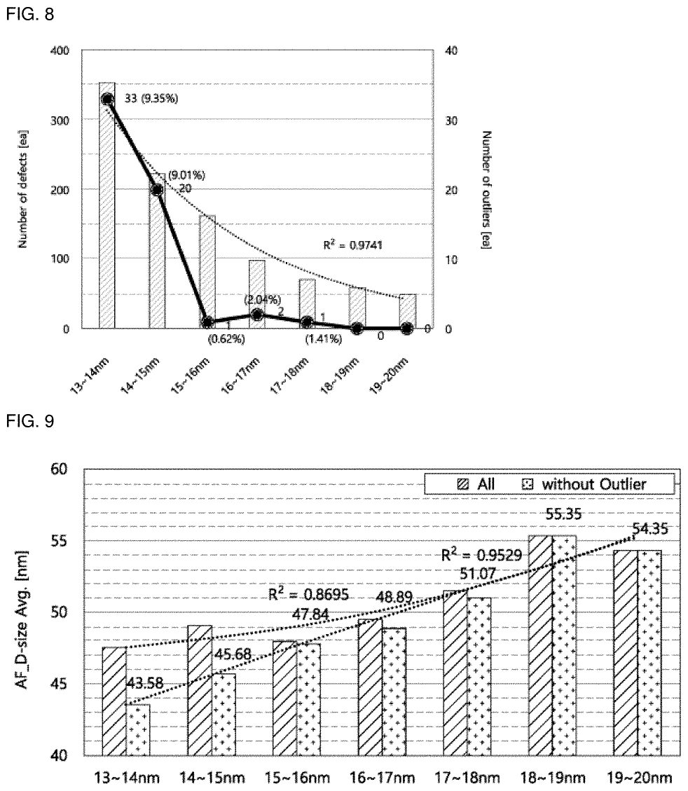

FIG. 8 shows the ratio of the defects determined to be noise to the total number of sample defects in FIGS. 7A to 7G.

As can be seen from FIG. 8, as the size of the defects before deposition of the thin film increases, the number of defects determined to be noise decreases due to the increased size of the defects after deposition of the thin film. The number of the defects determined to be noise may be expressed as the number of outliers (ea).

FIG. 9 shows the average size of defects after thin film deposition in each size range of defects.

In FIG. 9, in each size range of defects, the left side shows the average size of all defects after thin film deposition, and the right side shows the average size of remaining defects excluding the defects determined to be noise, among the defects after thin film deposition. Accordingly, the size increase after thin film deposition of the remaining defects excluding the outlier defects, which are the defects determined to be noise, can be seen more clearly.

Based thereon, according to the method for determining fine particle defects on a silicon wafer according to the present invention, first defects are detected on the surface of the silicon wafer, a thin film is deposited thereon, second defects are detected thereon, whether or not additional defects are formed after deposition of the thin film is determined using the method, and noise is removed therefrom, so ultrafine particle defects present on the surface of the silicon wafer can be detected before thin film deposition, particularly, before detection of first defects.

As is apparent from the above description, the method for determining fine particle defects on a silicon wafer according to the present invention includes detecting first defects on the surface of the silicon wafer, depositing a thin film thereon, detecting second defects thereon, determining whether or not additional defects are formed after deposition of the thin film using the method, and removing noise from the additional defects, thereby enabling detection of ultrafine particle defects present on the surface of the silicon wafer before thin film deposition, particularly, before detection of the first defects.

Although embodiments of the present invention have been described in more detail with reference to the attached drawings, those skilled in the art will appreciate that various modifications, additions and substitutions are possible, without departing from the scope and spirit of the invention as disclosed in the accompanying claims. These embodiments are provided to illustrate the present invention, and should not be construed as limiting the scope of the present invention.

Therefore, it should be interpreted that the aforementioned embodiments are exemplary in all respects and are not restrictive. Furthermore, it should be construed that the protection scope of the present invention is defined by the following claims, and all technical ideas within the scope equivalent thereto also fall within the scope of the present invention.

What is claimed is:

1. A method for determining ultrafine particle defects, comprising:
detecting first defects on a surface of a silicon wafer;
forming a thin film on the silicon wafer;
detecting second defects on the surface of the silicon wafer having the thin film formed thereon;
comparing the first defects with the second defects to determine whether or not there are additional defects; and
removing noise from the additional defects.

2. The method according to claim 1, wherein the step of determining whether or not there are additional defects comprises determining second defects located beyond a predetermined distance from the first defects to be additional defects.

3. The method according to claim 1, wherein the step of removing noise from the additional defects comprises assigning a specific symbol to each of second defects based on characteristics of second defects by a second defect detector.

4. The method according to claim 3, wherein the specific symbol assigned to each of the second defects is A, B, or C, and among the specific symbols A to C, the second defects having the specific symbol C are the largest and the seconds defect having the specific symbol B are the smallest.

5. The method according to claim 4, wherein the second defects having the specific symbol C are determined to be noise.

6. The method according to claim 4, wherein the second defects having the specific symbol A comprise particle defects and bump defects.

7. The method according to claim 6, wherein the particle defects, among the second defects having the specific symbol A, are determined to be noise.

8. The method according to claim 6, wherein the bump defects, among the second defects having the specific symbol A, are determined to be noise.

9. The method according to claim 6, wherein the second defects having the specific symbol B comprise ultrafine particle defects and bump defects.

10. The method according to claim 9, wherein the ultrafine particle defects, among the second defects having the specific symbol B, have a smaller size than particle defects, among the second defects having the specific symbol A.

11. The method according to claim 9, wherein the bump defects, among the second defects having the specific symbol B, have a smaller size than bump defects, among the second defects having the specific symbol A.

12. The method according to claim 9, wherein the first defects having a 1-1 size before the formation of the thin film are changed to second defects having a 2-1 size, which is larger than the 1-1 size, after the formation of the thin film.

13. The method according to claim 12, wherein among the second defects having the specific symbol B, second defects smaller than the 2-1 size are determined to be bump defects.
